(19) United States
(12) Patent Application Publication
(10) Pub. No.: US 2007/0087581 A1
(43) Pub. Date: Apr. 19, 2007

(54) TECHNIQUE FOR ATOMIC LAYER DEPOSITION

(75) Inventors: Vikram SINGH, North Andover, MA (US); Harold M. Persing, Rockport, MA (US); Edmund J. Winder, Waltham, MA (US); Anthony Renau, West Newbury, MA (US); George Demetrios Papasouliotis, North Andover, MA (US)

Correspondence Address: HUNTON & WILLIAMS LLP/VARIAN SEMICONDUCTOR,;EQUIPMENT ASSOCIATES, INC., INTELLECTUAL PROPERTY DEPARTMENT, 1900 K STREET, N.W., SUITE 1200, WASHINGTON, DC, 20006-1109, US

(73) Assignee: Varian Semiconductor Equipment Associates, Inc., Gloucester, MA (US)

(21) Appl. No.: 11/608,522

(22) Filed: Dec. 8, 2006

Related U.S. Application Data
(63) Continuation-in-part of application No. 11/221,710, filed on Sep. 9, 2005.

(51) Int. Cl. H01L 21/31; H01L 21/469

(52) U.S. Cl. 438/780

(57) ABSTRACT

A technique for atomic layer deposition is disclosed. In one particular exemplary embodiment, the technique may be realized by a method for forming a strained thin film. The method may comprise supplying a substrate surface with one or more precursor substances having atoms of at least one first species and atoms of at least one second species, thereby forming a layer of the precursor substance on the substrate surface. The method may also comprise exposing the substrate surface to plasma-generated metastable atoms of a third species, wherein the metastable atoms desorb the atoms of the at least one second species from the substrate surface to form an atomic layer of the at least one first species. A desired amount of stress in the atomic layer of the at least one first species may be achieved by controlling one or more parameters in the atomic layer deposition process.

### CROSS-REFERENCE TO RELATED APPLICATIONS

This patent application is a continuation-in-part of U.S. patent application Ser. No. 11/221,710, filed Sep. 9, 2005, which is hereby incorporated by reference herein in its entirety.

### FIELD OF THE DISCLOSURE

The present disclosure relates generally to semiconductor manufacturing and, more particularly, to a technique for atomic layer deposition.

### BACKGROUND OF THE DISCLOSURE

Modern semiconductor manufacturing has created a need for precision, atomic-level deposition of high quality thin film structures. Responsive to this needs a number of film growth techniques collectively known as “atomic layer deposition” (ALD) or “atomic layer epitaxy” (ALE) have been developed in recent years. ALD technology is capable of depositing uniform and conformal films with atomic layer accuracy. A typical ALD process uses sequential self-limiting surface reactions to achieve control of film growth in the monolayer thickness regime. Due to its excellent potential for film conformity and uniformity, ALD has become the technology of choice for advanced applications such as high dielectric constant (high-k) gate oxide, storage capacitor dielectrics, and copper diffusion barriers in microelectronic devices. In fact, ALD technology may be useful for any advanced application that benefits from precise control of thin film structure on the nanometer (nm) or sub-nanometer scale.

To date, however, most existing deposition techniques suffer from inherent deficiencies and have not been reliably applied to mass production in the semiconductor industry. For example, a deposition technique known as “molecular beam epitaxy” (MBE) uses shutter-controlled individual effusion cells to direct atoms of different species towards a substrate surface, on which these atoms react with each other to form a desired monolayer. In a solid-source MBE process, the effusion cells have to be heated to considerably high temperatures for thermionic emission of the ingredient atoms. In addition, extremely high vacuum has to be maintained to ensure no collision among the ingredient atoms before they reach the substrate surface. Despite the high temperature and high vacuum requirement, MBE film growth rates are quite low for mass production purposes.

Another ALD technique is known as temperature-modulated atomic layer epitaxy (ALE). To grow a silicon film according to this technique, the following steps are repeated. First, a monolayer of silane (SiH₄) is deposited on a substrate surface at a relatively low temperature between 180° C. and 400° C. Then, the substrate temperature is ramped to approximately 550° C. to desorb the hydrogen atoms, leaving behind a monolayer of silicon. Although this technique does achieve a controlled layer-by-layer film growth, the requirement for repeated temperature spikes makes it difficult to maintain uniformity across large wafers and repeatability from layer to layer. Additionally, heating the substrate to high temperatures can damage or destroy delicate structures formed on the substrate in previous processing steps.

One existing ALD technique employs ion bombardment to desorb excess hydrogen atoms. According to this technique, a disilane (Si₂H₆) gas may be used to form a disilane monolayer on a substrate surface. The substrate surface is then bombarded with helium or argon ions to desorb excess hydrogen atoms from the disilane monolayer to form a silicon monolayer. Perhaps due to overly energetic ion bombardments (˜50 eV ion energy), the film growth rate is fairly low (less than 0.15 monolayer per cycle) , and energetic ion fluxes are essentially line-of-sight processes which therefore can compromise atomic layer deposition's potential for a highly conformal deposition. Further, the energetic ion can also cause crystalline defects which may necessitate post-deposition annealing.

Further, conformal doping for ALD-deposited thin films, especially in 3-D structures (e.g., FinFETs), remains a challenge to process engineers. Existing ion implantation techniques are undesirable for introducing dopants into a 3-D conformally covered structure, not only because it is hard to achieve uniformity of dopant distribution, but also due to the potential damages that may result from a post-implant anneal.

In view of the foregoing, it would be desirable to provide an atomic layer deposition solution which overcomes the above-described inadequacies and shortcomings.

### SUMMARY OF THE DISCLOSURE

A technique for atomic layer deposition is disclosed. In one particular exemplary embodiment, the technique may be realized by a method for forming a strained thin film. The method may comprise supplying a substrate surface with one or more precursor substances having atoms of at least one first species and atoms of at least one second species, thereby forming a layer of the precursor substance on the substrate surface. The method may also comprise exposing the substrate surface to plasma-generated metastable atoms of a third species, wherein the metastable atoms desorb the atoms of the at least one second species from the substrate surface to form an atomic layer of the at least one first species. A desired amount of stress in the atomic layer of the at least one first species may be achieved by controlling one or more parameters selected from a group consisting of: a deposition temperature, a composition of the atomic layer of the at least one first species, an amount of impurities in the atomic layer of the at least one first species, and a flux or energy associated with the metastable atoms of the third species. These steps may be repeated in multiple deposition cycles until a desired film thickness is achieved.

In another particular exemplary embodiment, the technique may be realized as a method of forming a silicon nitride film. The method may comprise supplying a substrate surface with one or more precursor substances having silicon and nitrogen atoms, thereby forming a layer of the one or more precursor substances on the substrate surface. The method may also comprise exposing the substrate surface to plasma-generated metastable atoms of a third species, wherein the metastable atoms desorb excessive silicon and nitrogen atoms from the layer of the one or more precursor substances to form an atomic layer of silicon nitride. These steps may be repeated in multiple deposition cycles until a desired thickness of silicon nitride is achieved.

In yet another particular exemplary embodiment, the technique may be realized as a method of forming a silicon nitride film. The method may comprise supplying a substrate surface with one or more precursor substances having silicon atoms, thereby forming a layer of the one or more precursor substances on the substrate surface. The method may also comprise exposing the layer of the one or more precursor substances to plasma-generated metastable atoms of nitrogen to form an atomic layer of silicon nitride. These steps may be repeated in multiple deposition cycles until a desired thickness of silicon nitride is achieved.

The present disclosure will now be described in more detail with reference to exemplary embodiments thereof as shown in the accompanying drawings. While the present disclosure is described below with reference to exemplary embodiments, it should be understood that the present disclosure is not limited thereto. Those of ordinary skill in the art having access to the teachings herein will recognize additional implementations, modifications, and embodiments, as well as other fields of use, which are within the scope of the present disclosure as described herein, and with respect to which the present disclosure may be of significant utility.

### BRIEF DESCRIPTION OF THE DRAWINGS

In order to facilitate a fuller understanding of the present disclosure, reference is now made to the accompanying drawings, in which like elements are referenced with like numerals. These drawings should not be construed as limiting the present disclosure, but are intended to be exemplary only.

FIG. 1 shows a block diagram illustrating an exemplary atomic layer deposition cycle in accordance with an embodiment of the present disclosure.

FIG. 2 shows a block diagram illustrating an exemplary atomic layer deposition cycle in accordance with an embodiment of the present disclosure.

FIG. 3 shows a block diagram illustrating an exemplary system for atomic layer deposition in accordance with an embodiment of the present disclosure.

FIG. 4 shows a flow chart illustrating an exemplary method for atomic layer deposition in accordance with an embodiment of the present disclosure.

### DETAILED DESCRIPTION OF EXEMPLARY EMBODIMENTS

To solve the aforementioned problems associated with existing atomic layer deposition techniques, embodiments of the present disclosure introduce an ALD and in situ doping technique. Metastable atoms may be used to desorb excess atoms. The metastable atoms may be generated, for example, in a plasma chamber. For illustration purposes, the following description will focus on a method and apparatus for depositing doped or undoped silicon using helium metastable atoms. It should be appreciated that, with a same or similar technique, thin films of other species may also be grown using helium or other metastable atoms.

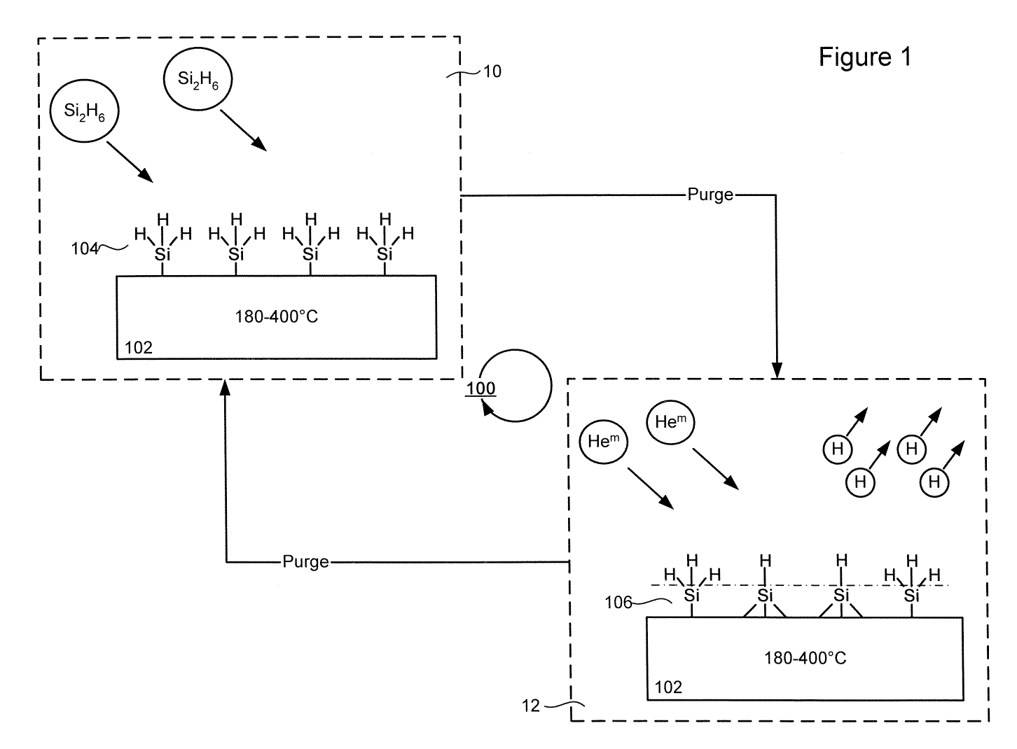

Referring to FIG. 1, there is shown a block diagram illustrating an exemplary atomic layer deposition cycle 100 in accordance with an embodiment of the present disclosure. The exemplary atomic layer deposition cycle 100 may comprise two phases, a saturation phase 10 and a desorption phase 12.

In the saturation phase 10, a substrate 102 may be exposed to a disilane (Si₂H₆) gas. For silicon film growth, the substrate surface may comprise, for example, silicon, silicon-on-insulator (SOI), and/or silicon dioxide. The disilane gas serves as a silicon precursor, and is supplied in a sufficiently high dose to saturate the substrate surface forming a disilane monolayer 104 thereon. Throughout this disclosure, however, use of the word “saturate” does not preclude the scenario where a substrate surface is only partially covered by a substance used to “saturate” such surface. The substrate 102 as well as the process environment may be kept at a carefully selected temperature to prevent the precursor gas from condensing or decomposing on the substrate surface. In this embodiment, the substrate 102 is heated to and maintained at a temperature between 180° C. and 400° C., although it is within the scope of the present disclosure to heat and maintain the substrate 102 within other temperature ranges.

In the desorption phase 12, the substrate 102 may be exposed to metastable atoms with sufficient energy to desorb the excess atoms from the precursor monolayer. According to this embodiment, helium metastable atoms may be used to desorb excess hydrogen atoms, either partially or completely, from the disilane monolayer 104 formed in the saturation phase 10. The helium metastable atoms may be created, for example, from a helium gas in an inductively coupled plasma. Each helium metastable atom may have an internal energy of approximately 20 eV, which can be used to break the bond between a silicon atom and a hydrogen atom. According to some embodiments, the metastable and other excited states of an inert gas (helium, argon, etc.) tend to emit photons that may also indirectly drive the desorption reactions at the substrate surface. After the excess hydrogen atoms have been removed, a silicon monolayer 106 may be formed on the substrate surface. According to some embodiments, not all of the excess hydrogen atoms may be removed. Therefore, at the end of the desorption phase 12, the surface of the silicon monolayer 106 may be a mixture of dangling bonds and hydrogen-terminated silicon atoms.

Between the saturation phase 10 and the desorption phase 12, the substrate surface may be purged with one or more inert gases (e.g., helium or argon) to remove the excess reaction gases as well as by-products (e.g., hydrogen). A complete cycle through the saturation phase 10 and the desorption phase 12, including the “purge” steps between the two phases, may be referred to as one “deposition cycle.” The deposition cycle 100 may be repeated to form a thin film of pure silicon (e.g., crystalline, polycrystalline, amorphous type, etc.), one monolayer (or fractional monolayer) at a time.

According to embodiments of the present disclosure, it may be advantageous to use metastable atoms rather than ions to desorb excess atoms from a substrate surface saturated with a precursor substance. Where the metastable atoms are generated in a plasma for desorption purposes, it may be desirable to prevent charged particles (e.g., electrons and ions) generated in the plasma from reaching the substrate surface, such that anisotropic film properties due to these charged particles may be reduced or minimized. A number of measures may be taken to prevent charged particles from affecting the ALD film formed on the substrate surface. For example, one or more devices (e.g., a baffle or screen) may be interposed between the plasma source and the substrate. These devices may further be biased filter out unwanted charged particles. Alternatively, an electromagnetic field may be set up to deflect charge particles. According to other embodiments, the orientation of the substrate surface may be adjusted to minimize the incident influx of charged particles. For example, the substrate platform may be inverted or otherwise turned away from the line of sight of the plasma source. Alternatively, the plasma source may be positioned at a distance from the substrate so as to cause a significant portion of the charged particles to fail to reach the substrate surface due to scattering or collisions.

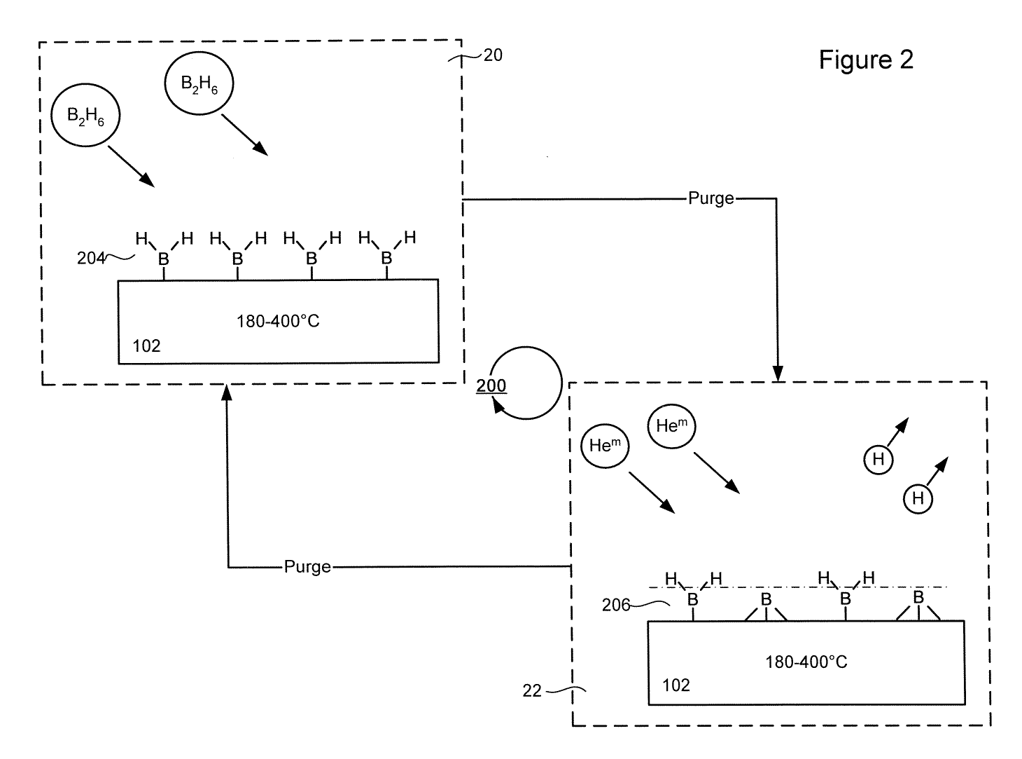

Referring to FIG. 2, there is shown a block diagram illustrating an exemplary atomic layer deposition cycle 200 in accordance with another embodiment of the present disclosure. According to this embodiment, the ALD process as illustrated in FIG. 1 above may be utilized not only to deposit a single-species thin film, but also to introduce impurities into the thin film or to form a multi-species and/or alternate-layered film, all in a well controlled manner. For example, apart from an undoped silicon film, a doped silicon film may also be grown based on a slightly modified ALD process. According to this modified ALD process, one or more deposition cycles 100 may be replaced with one or more deposition cycles 200.

In a saturation phase 20 of a deposition cycle 200, a dopant precursor gas may be provided in place of or concurrently with the silicon precursor gas. In the exemplary embodiment illustrated in FIG. 2, the dopant precursor is diborane (B₂H₆) which may adsorb (or “chemisorb”) to the surface of the substrate 102 to form a diborane monolayer 204. The underlying surface, in this case, may comprise a silicon monolayer deposited in a previous deposition cycle 100. The diborane monolayer 204 may partially or completely cover the underlying surface.

In a desorption phase 22 of a deposition cycle 200, the substrate 102 may be exposed to helium metastable atoms as described above. The helium metastable atoms may desorb excess hydrogen atoms from the diborane monolayer 204, leaving behind a partial or complete boron monolayer 206.

By controlling the number of deposition cycles 100 to be replaced with the deposition cycle 200, and by controlling the dose of diborane gas supplied in the saturation phase 20, a desired boron dopant density profile in the silicon film may be achieved. Since this in situ doping technique relies on conformal deposition of dopant atoms rather than ion implantation, it may achieve a uniform dopant distribution over the complex surface of a 3-D structure such as a FinFET. Further, there is no need for a post-deposition high-temperature diffusion process as required for ion implanted dopant atoms. Instead, no annealing or only a low-temperature annealing is needed, which results in reduced diffusion of the dopant species and therefore very abrupt (or “box-like”) dopant profiles. As such, embodiments of the present disclosure may be implemented at temperatures below 500° C., which is well within the semiconductor industry's “thermal budget.”

The atomic layer deposition in accordance with embodiments of the present disclosure may be a selective process depending on the substrate surface composition. For example, the process illustrated in FIG. 1 may deposit silicon monolayers on a silicon or SOI surface but not on a silicon dioxide (SiO₂) surface. Thus, silicon dioxide may be used as a masking layer to shield selected portions of the substrate surface.

It should be appreciated that, although only helium metastable atoms are used in the above examples, atoms of other species may also be chosen for the desorption process. Choice of these species may be based on the lifetime and energy of their metastable or excited states. Table 1 provides a list of candidate species whose metastable atoms may be used in the desorption phase of an ALD process.

TABLE 1

| Species | Lifetime (s) | Energy (eV) |
|---|---|---|
| He | 8000 | 19.8 |
| Ne | 24 | 17 |
| Ar | 40 | 12 |
| Kr | 30 | 10 |
| Xe | 43 | 8.4 |

It should also be appreciated that, apart from a diborane gas, other dopant precursors may also be used to introduce desired dopant atoms into ALD-formed thin films. Suitable dopant precursors for introducing dopant atoms such as boron (B), arsenic (As), phosphorus (P), indium (In), and antimony (Sb) may include but are not limited to the following classes of compounds: halides (e.g., BF₃), alkoxides (e.g., B(OCH₃)₃), alkyls (e.g., In(CH₃)₃), hydrides (e.g., AsH₃, PH₃), cyclopentadienyls, alkylimides, alkylamides (e.g., P[N(CH₃)₂]₃), and amidinates.

Further, the in situ doping technique, in which dopant-containing monolayers are deposited through an ALD-like process, is not limited to plasma-enhanced ALD processes. Nor does this in situ doping technique require the use of metastable atoms. For example, a thermal ALD process may also be adapted to form the dopant-containing monolayers. In fact, this in situ doping concept is applicable to any ALD process wherein one or more deposition cycles that deposit the monolayers of the thin film to be doped may be replaced with one or more deposition cycles that deposit the dopant-containing monolayers, or wherein the thin film to be doped may be deposited in substantially the same time as the dopant-containing monolayers.

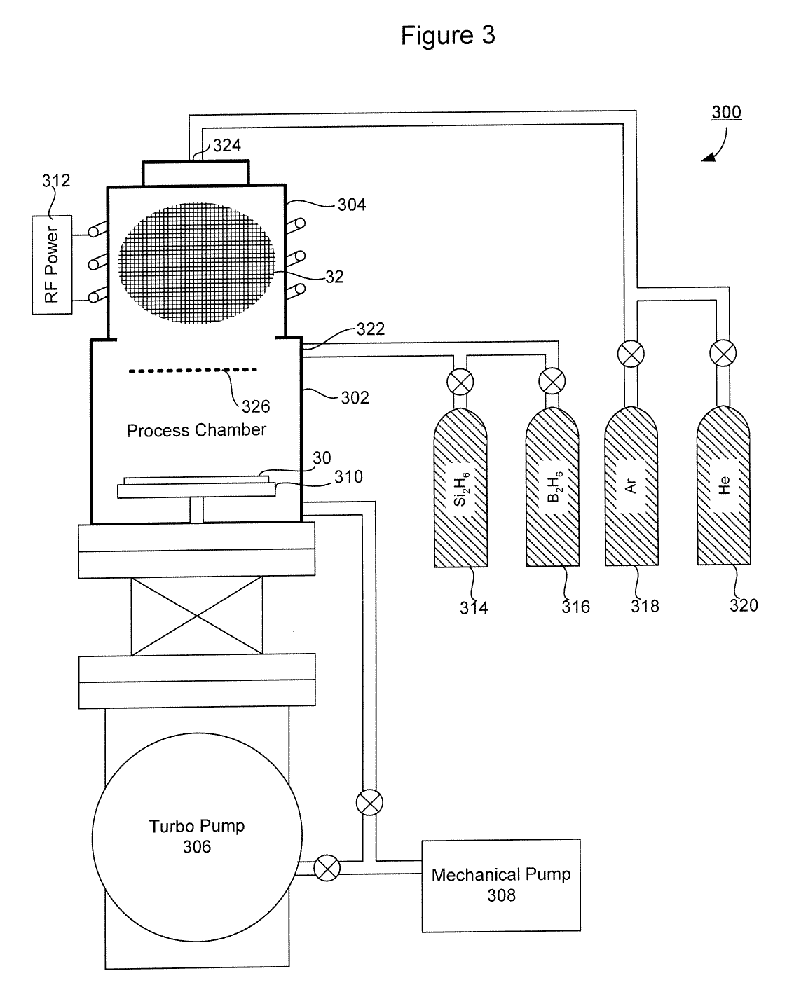

FIG. 3 shows a block diagram illustrating an exemplary system 300 for atomic layer deposition in accordance with an embodiment of the present disclosure.

The system 300 may comprise a process chamber 302, which is typically capable of a high vacuum base pressure (e.g., 10⁻⁷-10⁻⁶ torr) with, for example, a turbo pump 306, a mechanical pump 308, and other necessary vacuum sealing components. Inside the process chamber 302, there may be a substrate platform 310 that holds at least one substrate 30. The substrate platform 310 may be equipped with one or more temperature management devices to adjust and maintain the temperature of the substrate 30. Tilting or rotation of the substrate platform 30 may also be accommodated. The process chamber 302 may be further equipped with one or more film growth monitoring devices, such as a quartz crystal microbalance and/or a RHEED (reflection high energy electron diffraction) instrument.

The system 300 may also comprise a plasma chamber 304 which may be either coupled to or part of the process chamber 302. A radio frequency (RF) power supply 312 may be used to generate an inductively coupled plasma 32 inside the plasma chamber 304. For example, a helium gas supplied with a proper pressure may be excited by the RF power to generate a helium plasma which in turn generates helium metastable atoms.

The system 300 may further comprise a number of gas supplies, such as a disilane supply 314, a diborane supply 316, an argon supply 318, and a helium supply 320. Each gas supply may comprise a flow-control valve to set individual flow rates as desired. Alternately, the gas may be metered into the system by a series connection of, for example, a valve, a small chamber of fixed volume, and a second valve. The small chamber is first filled to the desired pressure by opening the first valve. After the first valve is closed, the fixed volume of gas is released into the chamber by opening the second valve. The disilane supply 314 and the diborane supply 316 may be coupled to the process chamber 302 through a first inlet 322, and may supply a sufficient amount of the respective silicon and boron precursor gases to saturate the substrate 30. The argon supply 318 and the helium supply 320 may be coupled to the plasma chamber 304 through a second inlet 324. The argon supply 318 may provide argon (or other inert gases) to purge the system 300. The helium supply 320 may supply a helium gas for plasma generation of helium metastable atoms. Optionally, there may be a screen or baffle device 326 between the plasma chamber 304 and the process chamber 302. The screen or baffle device 326, either biased or unbiased, may serve to prevent at least a portion of charged particles generated in the plasma chamber 304 from reaching the substrate 30.

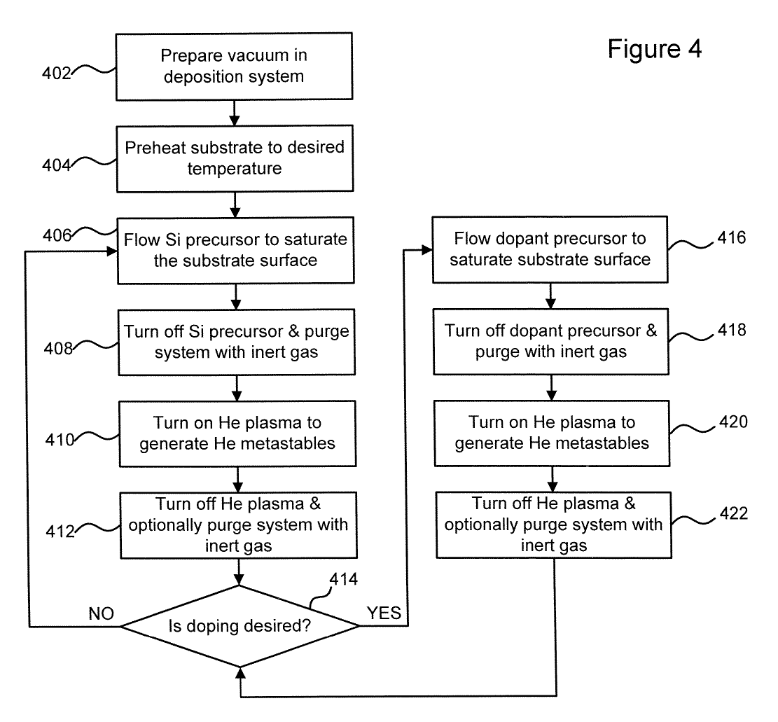

FIG. 4 shows a flow chart illustrating an exemplary method for atomic layer deposition in accordance with an embodiment of the present disclosure.

In step 402, a deposition system such as the one shown in FIG. 3 may be pumped down to a high-vacuum (HV) state. The vacuum condition may be achieved with any vacuum technology whether now known or later developed. The vacuum equipment may include, for example, one or more of a mechanical pump, a turbo pump, and a cryo pump. The vacuum level is preferably at least 10⁻⁷-10⁻⁶ torr, although it is within the scope of the present disclosure to maintain the vacuum level at other pressures. For example, if a higher film purity is desired, an even higher base vacuum may be needed. For a low-purity film, a lower vacuum may be acceptable.

In step 404, a substrate may be preheated to a desired temperature. The substrate temperature may be determined based on substrate type, ALD reaction species, desired growth rate, etc.

In step 406, a silicon precursor gas such as disilane (and its carrier gas, if any) may be flowed into a process chamber where the substrate sits. The silicon precursor gas may be supplied at a flow rate or pressure sufficient to saturate the substrate surface. The flow of disilane may last, for example, for a few seconds or up to a few tens of seconds. A monolayer of disilane may partially or completely cover the substrate surface.

In step 408, after surface saturation, the silicon precursor may be turned off and the deposition system may be purged with one or more inert gases to remove the excess silicon precursor.

In step 410, a helium plasma may be turned on. That is, a helium gas may be flowed from a plasma chamber to the process chamber. The helium plasma may be an inductively coupled plasma (ICP) or any of a number of other plasma types that provide enough excitation to the helium atoms to create helium metastable atoms. The substrate in the process chamber may be exposed to the helium metastable atoms so that they may react with the adsorbed silicon precursor thereon to desorb the non-silicon atoms. For example, for a disilane monolayer, the helium metastable atoms may help remove the excess hydrogen atoms to form a desired silicon monolayer. Exposure of the substrate surface to the metastable atoms may last, for example, for a few seconds or up to a few tens of seconds.

In step 412, the helium plasma may be turned off and the deposition system may be again purged with one or more inert gases.

In step 414, it may be determined whether any doping of the silicon film is desired. If doping is desired and it is an appropriate time to introduce dopants, the process may branch to step 416. Otherwise, the process may loop back to step 406 to start depositing a next monolayer of silicon and/or finish depositing a partial monolayer of silicon.

In step 416, a dopant precursor gas such as diborane (and its carrier gas, if any) may be flowed into the process chamber. The dopant precursor gas may be supplied at a flow rate or pressure sufficient to saturate the substrate surface. The flow of diborane may last, for example, for a few seconds or up to a few tens of seconds. A monolayer of diborane may partially or completely cover the substrate surface.

In step 418, after surface saturation, the dopant precursor may be turned off and the deposition system may be purged with one or more inert gases to remove the excess dopant precursor.

In step 420, the helium plasma may be turned on to generate helium metastable atoms. The substrate in the process chamber may again be exposed to the helium metastable atoms so that they may react with the adsorbed dopant precursor thereon to desorb the non-dopant atoms. For example, for a diborane monolayer, the helium metastable atoms may help remove the excess hydrogen atoms to form a desired partial or complete boron monolayer. Exposure of the substrate surface to the metastable atoms may last, for example, for a few seconds or up to a few tens of seconds.

In step 422, the helium plasma may be turned off and the deposition system may be again purged with one or more inert gases.

The above-described process steps of 406 through 412 and/or the process steps of 416 through 422 may be repeated until a desired silicon film with one or more monolayers with desired dopant profile has been obtained.

It should be understood that, although the above examples only describe the deposition and/or doping of a silicon film, embodiments of the present disclosure may be easily adapted to deposit or dope thin films of other materials or species. For example, ALD thin films containing the following species may also be deposited or doped: germanium (Ge), carbon (C), gallium (Ga), arsenic (As), indium (In), aluminum (Al), or phosphorus (P). The resulting thin film may contain a single species such as carbon or germanium, or a compound such as III-V compounds (e.g., GaAs, InAlP). For this purpose, a precursor substance containing the corresponding species may be utilized. Candidates for the precursor substance may include but are not limited to: hydrides (e.g. SiH₄, Si₂H₆, GeH₄) or halogenated hydrides (e.g. SiHCl₃), halogenated hydrocarbons (such as CHF₃), alkyls (e.g. trimethyl aluminum—Al(CH₃)₃, or dimethyl ethyl aluminum—CH₃CH₂—Al(CH₃)₂), or halides (such as CCl₄ or CCl₂F₂).

In accordance with embodiments of the present disclosure, the above-described ALD and in-situ doping technique may be employed in a number of semiconductor manufacturing processes. In particular, the ALD and in-situ doping technique is beneficial where a relatively low-temperature process is preferred over a high-temperature process. Strain engineering and in-situ nitridation are two exemplary applications.

As feature sizes of semiconductor devices shrink beyond 90 nanometers, scaling alone can no longer produce desired device performance. Strain engineering is a promising approach to circumvent the scaling limits, wherein thin films (e.g., oxides, nitrides, silicon, or silicon germanium) with a high stress are introduced to take advantage of improved carrier mobility associated with a strained crystalline lattice. For instance, strain may be introduced in the silicon channel of a metal-oxide-semiconductor field-effect transistor (MOSFET) either locally (uniaxially) or globally to improve the MOSFET performance. Currently, high-temperature selective epitaxial growth techniques are employed to produce strained thin films such as in-situ doped silicon with p-type dopants (e.g., boron) or n-type dopants (e.g., arsenic and phosphorous). In addition, germanium may be mixed in with the dopants in conjunction with silicon for strain engineering. In some cases only silicon germanium (SiGe) is deposited without the dopants. However, the high temperatures associated with the conventional strain engineering processes make them less appealing for many applications.

According to embodiments of the present disclosure, the above-described metastable-enhanced ALD technique is an advantageous alternative for strain engineering processes such as the ones mentioned above. The doped or undoped silicon, SiGe or other strained thin films may be deposited with precision and at low temperature. The amount of stress in strained ALD thin films may be controlled by a number of parameters. For example, in the deposition of a strained SiGe film, the amount of germanium (e.g., compared to that of silicon) as well as the deposition temperature may be tuned to achieve a desired amount of stress. According to one embodiment, a desired SiGe film composition may be achieved by modulating its exposure (e.g., by number of cycles) to silicon and germanium precursors respectively. In addition, the amount of impurities (e.g., carbon) in the ALD thin film may have some secondary effect on the amount of stress therein. The advantage of the lower temperature lies in less dopant diffusion during the in-situ doping or deposition processes. Additionally, with lower temperature deposition there may be more strain for the same amount of germanium because of less strain relaxation.

As described above, a metastable-enhanced ALD process may comprise multiple deposition cycles, each including exposure of a substrate to a precursor followed (and/or preceded) by exposure to metastable atoms. The same or different ALD deposition cycles may be repeated until a desired film thickness is reached. To precisely control the amount of stress in a strained thin film, process parameters may be varied on per-cycle basis. For example, in one ALD deposition cycle, a substrate surface may be exposed to a first type of precursor (e.g., silicon precursor) while, in another ALD deposition cycle, the substrate surface may be exposed to a second type of precursor (e.g., germanium precursor). For another example, there may be different amount or types of dopants introduced in different ALD deposition cycles. According to one embodiment, a cocktail of dopants may be introduced concurrently in a same ALD deposition cycle.

As to in-situ nitridation, high-temperature (>650° C.) low-pressure chemical vapor deposition (LPCVD) processes are currently employed to deposit conformal silicon nitride (Si₃N₄) films from mixtures of dichlorosilane (SiH₂Cl₂) and ammonia (NH₃). In addition, ALD processes causing alternating exposure to SiH₂Cl₂and NH₃have been practiced at temperatures above 650° C. Precursors containing silicon, nitrogen and carbon have been used for deposition of nitride films. However, carbon content in nitride films increases drastically as deposition temperature drops below 600° C. with corresponding degradation of electrical properties (e.g., formation of leaky films), which phenomenon has thus far dictated 650+° C. high temperatures for in-situ nitridation processes. As thermal budget for the manufacturing of semiconductor devices is decreasing, there is a need for deposition of low-temperature, conformal Si₃N₄ films for spacer and liner applications. In addition, Si₃N₄ films of higher stress are desirable in order to increase overall stress of a gate stack in a MOSFET as part of a strain engineering strategy.

According to embodiments of the present disclosure, Si₃N₄ thin film structures (e.g., spacers) may be deposited using the metastable-enhanced ALD technique at relatively low temperatures. Since the energy necessary for film growth is provided by metastable species, a metastable-enhanced ALD process may achieve conformal coverage at temperatures below 400° C. The deposition may be performed with individual precursors for silicon and nitrogen respectively or a single precursor containing both elements. And, metastables may be introduced to desorb excess atoms and/or remove ligands from the adsorbed precursors. In some embodiments, a conformal silicon-containing film may be transformed into a Si₃N₄ film via exposure to a nitrogen containing metastable flux. Beyond film conformity and low deposition temperature, an additional advantage of this approach is a minimal incorporation of impurities (e.g., chlorine and carbon) into the Si₃N₄ film.

The present disclosure is not to be limited in scope by the specific embodiments described herein. Indeed, other various embodiments of and modifications to the present disclosure, in addition to those described herein, will be apparent to those of ordinary skill in the art from the foregoing description and accompanying drawings. Thus, such other embodiments and modifications are intended to fall within the scope of the present disclosure. Further, although the present disclosure has been described herein in the context of a particular implementation in a particular environment for a particular purpose, those of ordinary skill in the art will recognize that its usefulness is not limited thereto and that the present disclosure may be beneficially implemented in any number of environments for any number of purposes. Accordingly, the claims set forth below should be construed in view of the full breadth and spirit of the present disclosure as described herein.

1. A method for forming a strained thin film, the method comprising the steps of:
supplying a substrate surface with one or more precursor substances having atoms of at least one first species and atoms of at least one second species, thereby forming a layer of the precursor substance on the substrate surface; and
exposing the substrate surface to plasma-generated metastable atoms of a third species, wherein the metastable atoms desorb the atoms of the at least one second species from the substrate surface to form an atomic layer of the at least one first species;
wherein a desired amount of stress in the atomic layer of the at least one first species is achieved by controlling one or more parameters selected from a group consisting of: a deposition temperature, a composition of the atomic layer of the at least one first species, an amount of impurities in the atomic layer of the at least one first species, and a flux or energy associated with the metastable atoms of the third species.

2. The method according to claim 1, further comprising:
supplying the substrate surface with one or more dopant precursors to dope the atomic layer of the at least one first species.

3. The method according to claim 2, wherein a cocktail of two or more dopants are introduced, either concurrently or in sequence, into the atomic layer of the at least one first species.

4. The method according to claim 1, wherein:
the atomic layer of the at least one first species comprises silicon and germanium; and
the desired amount of stress is achieved at least in part by controlling an amount of germanium in the atomic layer of the at least one first species.

5. The method according to claim 4, further comprising:
tuning the desired amount of stress by controlling an amount of carbon introduced into the atomic layer of the at least one first species.

6. The method according to claim 1, further comprising:
repeating the steps recited therein in multiple deposition cycles until a desired thickness is achieved for the atomic layer of the at least one first species.

7. The method according to claim 6, wherein at least one deposition cycle comprises:
supplying the substrate surface with a first precursor;
exposing the substrate surface to metastable atoms of a first selected species;
supplying the substrate surface with a second precursor; and
exposing the substrate surface to metastable atoms of a second selected species.

8. The method according to claim 6, wherein at least one deposition cycle comprises:
exposing the substrate surface to metastable atoms of a first selected species
supplying the substrate surface with a first precursor;
exposing the substrate surface to metastable atoms of a second selected species;
supplying the substrate surface with a second precursor; and
exposing the substrate surface to metastable atoms of a third selected species;
wherein the first, the second, and the third selected species are of the same or different types.

9. The method according to claim 6, wherein the one or more precursor substances are not the same for all the deposition cycles.

10. The method according to claim 9, further comprising:
supplying the substrate surface with a silicon precursor;
exposing the substrate surface to metastable atoms of a first selected species;
supplying the substrate surface with a germanium precursor;
exposing the substrate surface to metastable atoms of a second selected species, wherein the first and the second selected species are of the same or different types; and
repeating the above-recited sequence until a silicon-germanium film with a desired amount of stress and a desired thickness is formed on the substrate surface.

11. The method according to claim 9, further comprising:
supplying the substrate surface with a silicon precursor and a germanium precursor concurrently;
exposing the substrate surface to metastable atoms of a selected species; and
repeating the above-recited sequence until a silicon-germanium film with a desired amount of stress and a desired thickness is formed on the substrate surface.

12. The method according to claim 1, wherein the one or more precursor substances comprise one or more species selected from a group consisting of:
silicon;
carbon;
germanium;
gallium;
arsenic;
indium;
aluminum; and
phosphorus.

13. The method according to claim 1, wherein the substrate surface comprises one or more materials selected from a group consisting of:
silicon;
silicon-on-insulator (SOI);
silicon dioxide;
diamond;
silicon germanium;
silicon carbide;
a III-V compound;
a flat panel material;
a polymer; and
a flexible substrate material.

14. The method according to claim 1, wherein the at least one third species comprises one or more species selected from a group consisting of:
helium (He);
neon (Ne)
argon (Ar);
krypton (Kr);
radon (Rn); and
xenon (Xe).

15. A method of forming a silicon nitride film, the method comprising the steps of:
supplying a substrate surface with one or more precursor substances having silicon and nitrogen atoms, thereby forming a layer of the one or more precursor substances on the substrate surface; and
exposing the substrate surface to plasma-generated metastable atoms of a third species, wherein the metastable atoms desorb excessive silicon and nitrogen atoms from the layer of the one or more precursor substances to form an atomic layer of silicon nitride.

16. The method according to claim 15, further comprising:
repeating the steps recited therein in multiple deposition cycles until a desired thickness of silicon nitride is achieved.

17. The method according to claim 15, wherein the silicon and nitrogen atoms are supplied to the substrate surface in their respective precursor substances.

18. The method according to claim 15, wherein the silicon and nitrogen atoms are supplied to the substrate surface in a single precursor substance.

19. The method according to claim 15, wherein the at least one third species comprises one or more species selected from a group consisting of:
helium (He);
neon (Ne);
argon (Ar);
krypton (Kr);
radon (Rn); and
xenon (Xe).

20. The method according to claim 15, wherein the substrate surface comprises one or more materials selected from a group consisting of:
silicon;
silicon-on-insulator (SOI);
silicon dioxide;
diamond;
silicon germanium;
silicon carbide;
a III-V compound;
a flat panel material;
a polymer; and
a flexible substrate material.

21. The method according to claim 15, wherein the substrate surface is kept at a temperature below 900° C.

22. A method of forming a silicon nitride film, the method comprising the steps of:
supplying a substrate surface with one or more precursor substances having silicon atoms, thereby forming a layer of the one or more precursor substances on the substrate surface; and
exposing the layer of the one or more precursor substances to plasma-generated metastable atoms of nitrogen to form an atomic layer of silicon nitride.

23. The method according to claim 22, further comprising:
repeating the steps recited therein in multiple deposition cycles until a desired thickness of silicon nitride is achieved.

24. The method according to claim 22, wherein the substrate surface comprises one or more materials selected from a group consisting of:
silicon;
silicon-on-insulator (SOI);
silicon dioxide;
diamond;
silicon germanium;
silicon carbide;
a III-V compound;
a flat panel material;
a polymer; and
a flexible substrate material.
